(19) United States
(12) Patent Application Publication
(10) Pub. No.: US 2019/0259641 A1
(43) Pub. Date: Aug. 22, 2019

(54) LIQUID CHEMICAL RECYCLE SYSTEM, LIQUID CHEMICAL SUPPLY SYSTEM, AND METHOD OF MANUFACTURING SEMICONDUCTOR DEVICE USING THE LIQUID CHEMICAL RECYCLE SYSTEM

(71) Applicant: Samsung Electronics Co., Ltd., Suwon-si (KR)

(72) Inventors: Young-Hoo KIM, Yongin-si (KR); Sung Hyun PARK, Daegu (KR); Hyun Woo NHO, Yongin-si (KR); Ji Hoon CHA, Seoul (KR); Yong Jun CHOI, Gwacheon-si (KR)

(21) Appl. No.: 16/115,943

(22) Filed: Aug. 29, 2018

(30) Foreign Application Priority Data
Feb. 20, 2018 (KR) 10-2018-0019746

(51) Int. Cl. H01L 21/67; B01D 29/66; H01L 21/311

(52) U.S. Cl. CPC H01L 21/67075; H01L 21/31111; B01D 29/66

(57) ABSTRACT

A liquid chemical recycle system includes a buffer tank receiving a first liquid chemical from outside; a vacuum tank having a vacuum pump connected thereto and receiving the first liquid chemical from the buffer tank using the vacuum pump; and a recycle tank receiving the first liquid chemical from the vacuum tank and providing a second liquid chemical, which is a recycled first liquid chemical, to the outside, wherein the buffer tank includes a first injection portion, to which the first liquid chemical is provided, and a first supply portion, which provides the first liquid chemical to the vacuum tank, and a bottom of the buffer tank is downwardly inclined toward the first supply portion to prevent a material contained in the first liquid chemical from being accumulated in the buffer tank.

### CROSS-REFERENCE TO RELATED APPLICATION

Korean Patent Application No. 10-2018-0019746, filed on Feb. 20, 2018, in the Korean Intellectual Property Office, and entitled: “Liquid Chemical Recycle System, Liquid Chemical Supply System, and Method of Manufacturing Semiconductor Device Using the Liquid Chemical Recycle System,” is incorporated by reference herein in its entirety.

### BACKGROUND

### 1. Field

Embodiments relate to a liquid chemical recycle system, a liquid chemical supply system, and a method of manufacturing a semiconductor device using the liquid chemical recycle system.

### 2. Description of the Related Art

In accordance with the replacement of generations of semiconductors, the generation of etching equipment has shifted from batch-type silicon etching equipment to single wafer-type etching equipment.

### SUMMARY

Embodiments are directed to a liquid chemical recycle system, including a buffer tank receiving a first liquid chemical from outside; a vacuum tank having a vacuum pump connected thereto and receiving the first liquid chemical from the buffer tank using the vacuum pump: and a recycle tank receiving the first liquid chemical from the vacuum tank and providing a second liquid chemical, which is a recycled first liquid chemical, to the outside, wherein the buffer tank includes a first injection portion, to which the first liquid chemical is provided, and a first supply portion, which provides the first liquid chemical to the vacuum tank, and a bottom of the buffer tank is downwardly inclined toward the first supply portion to prevent a material contained in the first liquid chemical from being accumulated in the buffer tank.

Embodiments are also directed to a liquid chemical supply system, including a first storage tank including a first level sensor and storing a first liquid chemical; a second storage tank including a second level sensor and storing a second liquid chemical; a main tank connected to the first and second storage tanks and receiving one of the first and second liquid chemicals; a process chamber receiving one of the first and second liquid chemicals from the main tank and in which a wet etching process is performed; a buffer tank receiving a third liquid chemical, which is used in the wet etching process, from the process chamber; and a vacuum tank including a third level sensor and receiving the third liquid chemical from the buffer tank, wherein the third liquid chemical is provided to the vacuum tank along an inclined surface of the buffer tank to prevent a material contained in the third liquid chemical from being accumulated in the buffer tank.

Embodiments are also directed to a method of manufacturing a semiconductor device, including providing a substrate including a first thin film; and removing at least part of the first thin film by performing a wet etching process on the substrate, wherein the wet etching process involves using a liquid chemical recycle system, and the liquid chemical recycle system includes: a buffer tank receiving a first liquid chemical from a process chamber; a vacuum tank having a vacuum pump connected thereto and receiving the first liquid chemical from the buffer tank using the vacuum pump; and a recycle tank receiving the first liquid chemical from the vacuum tank and providing a second liquid chemical, which is a recycled first liquid chemical, to the process chamber, wherein the buffer tank includes a first injection portion, to which the first liquid chemical is provided, and a first supply portion, which provides the first liquid chemical to the vacuum tank, and a bottom of the buffer tank is downwardly inclined toward the first supply portion to prevent a material contained in the first liquid chemical from being accumulated in the buffer tank.

### BRIEF DESCRIPTION OF THE DRAWINGS

Features will become apparent to those of skill in the art by describing in detail example embodiments with reference to the attached drawings in which:

FIG. 1 illustrates a schematic view of a liquid chemical supply system according to an example embodiment.

FIG. 2 illustrates a schematic view of level sensors according to an example embodiment.

FIG. 3 illustrates a schematic view of a solid solute precipitated in a buffer tank according to an example embodiment.

FIG. 4 illustrates a cross-sectional view of the buffer tank according to an example embodiment.

FIG. 5 illustrates a cross-sectional view of the precipitation of the solid solute that may occur in a vacuum tank according to an example embodiment.

FIG. 6 illustrates a cross-sectional view of the precipitation of the solid solute that may occur in a filter according to an example embodiment.

FIG. 7 illustrates a schematic view of a level sensor according to an example embodiment.

FIG. 8A illustrates a schematic view of level sensors according to an example embodiment.

FIG. 8B illustrates an enlarged view of an area S of FIG. 8A.

FIG. 9 illustrates a schematic view of the buffer tank of FIG. 3, as viewed from a positive Z-axis direction.

FIGS. 10, 12, and 14 illustrate cross-sectional views taken along line A-A′ of FIG. 9.

FIGS. 11, 13, and 15 illustrate cross-sectional views taken along line B-B′ of FIG. 9.

FIGS. 16 through 18 illustrate cross-sectional views of vacuum tanks according to an example embodiment.

FIG. 19 illustrates a schematic view of the flushing of a filter according to an example embodiment.

FIG. 20 illustrates a flowchart illustrating a method of manufacturing a semiconductor device according to an example embodiment.

### DETAILED DESCRIPTION

Embodiments will become more apparent to one of skill in the art by referencing the detailed description set forth herein.

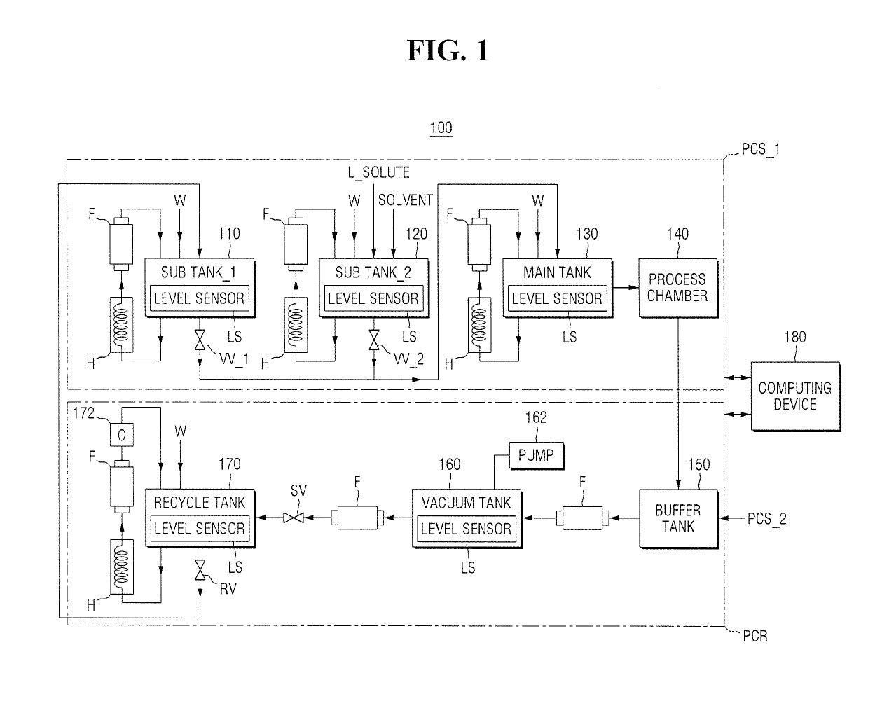

FIG. 1 illustrates a schematic view of a liquid chemical supply system according to an example embodiment.

Referring to FIG. 1, a liquid chemical supply system 100 may include first and second process liquid chemical supply systems PCS_1 and PCS_2, a process liquid chemical recycle system PCR, and a computing device 180.

For convenience, FIG. 1 only illustrates in detail the first process liquid chemical supply system PCS_1 and the process liquid chemical recycle system PCR. The second process liquid chemical supply system PCS_2 may have the same structure as, or a similar structure to, the first process liquid chemical supply system PCS_1 and, as such, a detailed illustration of the second process liquid chemical supply system PCS_2 is not repeated in FIG. 1.

In the present example embodiment, the first process liquid chemical supply system PCS_1 may include a first sub-tank (“SUB TANK_1”) 110, a second sub-tank (“SUB TANK_2”) 120, a main tank (“MAIN TANK”) 130, and a process chamber (“PROCESS CHAMBER”) 140.

In the present example embodiment, the first sub-tank 110 may include a level sensor (“LEVEL SENSOR”) LS. A first liquid chemical may be stored in the first sub-tank 110. In the present example embodiment, the first liquid chemical may be a recycled liquid chemical. In the present example embodiment, the first liquid chemical may be the mixture of a solvent and a solute. For example, the first liquid chemical may be the mixture of recycled phosphoric acid (H₃PO₄) and liquid (e.g., suspended or dissolved) silica (SiO₂).

In the present example embodiment, water W may be supplied into the first sub-tank 110 to control the concentration of the first liquid chemical stored in-the first sub-tank 110. For example, the water W may be deionized (DI) water. In the present example embodiment, the first sub-tank 110 may receive a recycled liquid chemical, i.e., the first liquid chemical, from a recycle tank (“RECYCLE TANK”) 170 that will be described below.

In the present example embodiment, the first liquid chemical may be circulated in the first sub-tank 110. For example, the first liquid chemical may be continuously circulated through a heater H and a filter F. In an implementation, the filter F may not be provided. In an implementation, the first sub-tank 110 may include a pump for circulating the first liquid chemical. FIG. 1 illustrates an example in which the first liquid chemical passes through the heater H and then the filter F. In another implementation, the first liquid chemical may pass through the filter F first and may then be heated by the heater H.

In the present example embodiment, the second sub-tank 120 may include a level sensor LS. A second liquid chemical may be stored in the second sub-tank 120. In the present example embodiment, the second liquid chemical may be a non-recycled or fresh liquid chemical. In the present example embodiment, the second liquid chemical may be the mixture of a solvent and a solute. For example, the second liquid chemical may be the mixture of phosphoric acid and liquid (e.g., dissolved or suspended) silica.

In the present example embodiment, water W may be supplied into the second sub-tank 120 to control the concentration of the second liquid chemical stored in the second sub-tank 120. For example, the water W may be DI water. In the present example embodiment, the second sub-tank 120 may receive a solvent SOLVENT and a liquid solute L_SOLUTE from the outside (where the outside represents, e.g., a process chamber that processes a semiconductor wafer). Thus, the second liquid chemical may be obtained by mixing the solvent SOLVENT and the liquid solute L_SOLUTE in the second sub-tank 120.

In the present example embodiment, the second liquid chemical may be circulated in the second sub-tank 120. For example, the second liquid chemical may be continuously circulated through a heater H and a filter F. In an implementation, the filter F may not be provided. The system in which the second liquid chemical is circulated may be the same as, or similar to, the system in which the first liquid chemical is circulated, and thus, a detailed description thereof will not be repeated.

In the present example embodiment, one of the first and second liquid chemicals may be provided to the main tank 130 by turning on one of first and second valves VV_1 and VV_2. In the present example embodiment, the turning on or off of the first and second valves VV_1 and VV_2 may be controlled by the computing device 180. Herein, whichever of the first and second liquid chemicals is provided to the main tank 130 may be referred to as a third liquid chemical.

In the present example embodiment, the main tank 130 may include a level sensor LS. In the present example embodiment, water W may be supplied into the main tank 130 to control the concentration of the third liquid chemical stored in the main tank 130. For example, the water W may be DI water.

In the present example embodiment, the third liquid chemical may be circulated in the main tank 130. The system in which the third liquid chemical is circulated inside the main tank 130 may be the same as, or similar to, the system in which the first liquid chemical is circulated inside the first sub-tank 110, and thus, a detailed description thereof will not be repeated.

The main tank 130 may provide the third liquid chemical to the process chamber 140. The process chamber 140 may perform a wet etching process using the third liquid chemical provided thereto. For example, a substrate with a first thin film deposited thereon may be provided to the process chamber 140 with the third liquid chemical. Then, at least part of the first thin film may be etched by the third liquid chemical.

In the present example embodiment, the process chamber 140 may provide the byproducts of the wet etching process to the process recycle system PCR. Herein, a liquid chemical obtained by the wet etching process may be referred to as a fourth liquid chemical. In other words, the fourth liquid chemical may include the third liquid chemical, at least part of the first thin film, and the byproducts of a chemical reaction between the third liquid chemical and the first thin film.

In the present example embodiment, the process liquid chemical recycle system PCR may include a buffer tank (“BUFFER TANK”) 150, a vacuum tank (“VACUUM TANK”) 160, and the recycle tank 170.

In the present example embodiment, the buffer tank 150 may receive the fourth liquid chemical from the first and second process liquid chemical supply systems PCS_1 and PCS_2. For example, the buffer tank 150 may be or include a manifold. In the present example embodiment, the buffer tank 150 may receive the fourth liquid chemical from the process chamber 140. In an implementation, the fourth liquid chemical provided to the process chamber 140 may be filtered by a filter and may then be provided to the buffer tank 150.

Herein, the fourth liquid chemical provided to the vacuum tank 160 may be referred to as a fifth liquid chemical. In an implementation, the fifth liquid chemical may be provided directly to the vacuum tank 160 without being stored in the buffer tank 150. As illustrated in FIG. 1, the fifth liquid chemical may be provided to the vacuum tank 160 via a filter F. In another implementation, no filter F may be provided between the buffer tank 150 and the vacuum tank 160.

In the present example embodiment, the vacuum tank 160 may include a level sensor LS and a pump 162. The pump 162 may suck gas from the vacuum tank 160 and may thus form a negative pressure in the vacuum tank 160. By forming a negative pressure in the vacuum tank 160, the fifth liquid chemical may be more easily provided to the vacuum tank 160.

Herein, the fifth liquid chemical stored in the vacuum tank 160 may be referred as a sixth liquid chemical. In the present example embodiment, if the level of the sixth liquid chemical in the vacuum tank 160 exceeds a predefined level, a third valve SV may be turned on. When the third valve SV is turned on, the sixth liquid chemical may be provided to the recycle tank 170. In the present example embodiment, the computing device 180 may control the turning on or off of the third valve SV based on the value of the level sensor LS of the vacuum tank 160. Also, as illustrated in FIG. 1, the sixth liquid chemical may be provided to the recycle tank 170 via a filter F.

In the present example embodiment, the recycle tank 170 may include a level sensor LS. Herein, the sixth liquid chemical stored in the recycle tank 170 may be referred to as a seventh liquid chemical.

In the present example embodiment, water W may be supplied into the recycle tank 170 to control the concentration of the seventh liquid chemical stored in the recycle tank 170. For example, the water W may be DI water. In the present example embodiment, the recycle tank 170 may further include a liquid chemical densitometer “C” 172, which measures the concentration or density of the seventh liquid chemical.

In the present example embodiment, the seventh liquid chemical may be circulated in the recycle tank 170. For example, the seventh liquid chemical may be continuously circulated through a heater H and a filter F. In the present example embodiment, when the seventh liquid chemical is circulated, the liquid chemical densitometer 172 may measure the concentration of the seventh liquid chemical. In another implementation, the liquid chemical densitometer 172 may be provided in the recycle tank 170.

In the present example embodiment, some of the filters F may not be provided. Further, in an implementation, the recycle tank 170 may further include a pump, which is for circulating the seventh liquid chemical. FIG. 1 illustrates that the seventh liquid chemical passes through the heater H and then the filter F. In another implementation, the seventh liquid chemical may pass through the filter F first and may then be heated by the heater H.

In the present example embodiment, when the concentration of the seventh liquid chemical reaches a predetermined level, a fourth valve RV may be turned on. When the fourth valve RV is turned on, the recycle tank 170 may provide the seventh liquid chemical to the first sub-tank 110. Thus, when the fourth valve RV is turned on, the seventh liquid chemical stored in the recycle tank 170 may be provided to the first sub-tank 110 as the first liquid chemical.

In the present example embodiment, the computing device 180 may control the general operation of the liquid chemical supply system 100. For example, the computing device 180 may be connected to the level sensors LS. The computing device 180 may control the operations of the valves VV_1, VV_2, SV, and RV based on the values of the level sensors LS. In an implementation, the computing device 180 may include a display device and may provide current state information of the liquid chemical supply system 100 to the display device.

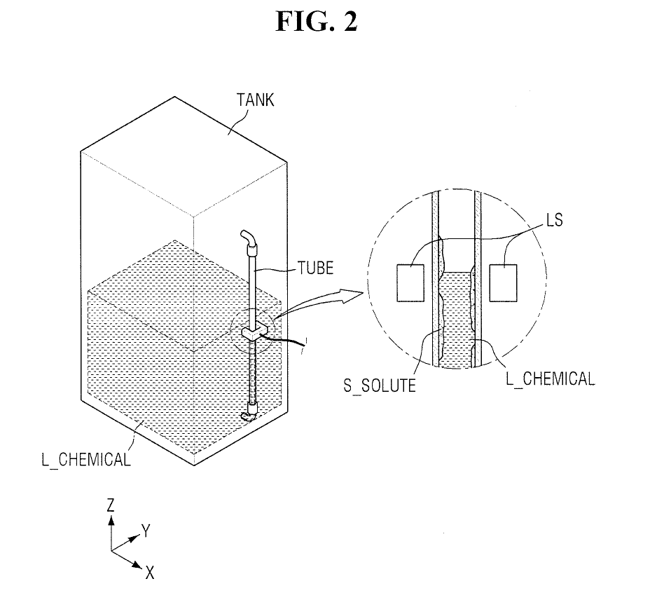

Level sensors according to an example embodiment and difficulties that may arise in connection with the level sensors will hereinafter be described with reference to FIG. 2.

FIG. 2 illustrates a schematic view of level sensors according to an example embodiment.

FIG. 2 illustrates level sensors LS and a tube TUBE, and the inset in FIG. 2 illustrates a cross-sectional view of the level sensors LS and the tube TUBE, taken along a Y-Z plane.

The tank TANK of FIG. 2 may be at least one of, for example, the first sub-tank 110, the second sub-tank 120, the main tank 130, the vacuum tank 160, and the recycle tank 170.

In the present example embodiment, the tube TUBE and the level sensors LS, which are connected to an exterior wall of the tank TANK, may be used to measure the level of a liquid chemical L_CHEMICAL stored in the tank TANK.

In the present example embodiment, the tube TUBE may be formed of a material that can transmit light therethrough. The level sensors LS may be, for example, photo sensors. The level sensors LS may be formed to surround or on opposite sides of the tube TUBE. For example, the level sensors LS may be formed to surround the tube TUBE in a U shape. First sides of the level sensors LS may send light. Second sides of the level sensors LS may receive light. In the present example embodiment, since the tube TUBE is formed of a material that can transmit light therethrough, light sent by the first sides of the level sensors LS passes through the tube TUBE and is then received by the second sides of the level sensors LS.

In the present example embodiment, if the level of the liquid chemical L_CHEMICAL stored in the tank TANK exceeds a predefined level, the second sides of the level sensors LS may not be able to receive light. In other words, if the level of the liquid chemical L_CHEMICAL increases and reaches the height where the level sensors LS are installed and thus scatters or absorbs light sent by the first sides of the level sensors LS, the second sides of the level sensors LS may not be able to receive light. In this case, a determination may be made that the level of the liquid chemical L_CHEMICAL stored in the tank TANK is raised to the height where the level sensors LS are installed. In the present example embodiment, if the second sides of the level sensors LS cannot receive light, the level sensors LS may send a predetermined signal to the computing device 180.

As illustrated in FIG. 2, the tube TUBE may be much thinner than the tank TANK. Thus, even if the liquid chemical L_CHEMICAL stored in the tank TANK is configured to be circulated, the liquid chemical L_CHEMICAL may not be able to be properly circulated through the tube TUBE. Also, since the tube TUBE is exposed on the outside of the tank TANK, the temperature of the liquid chemical L_CHEMICAL provided to the tube TUBE may be lower than the temperature of the liquid chemical L_CHEMICAL stored in the tank TANK. If the liquid chemical L_CHEMICAL is not sufficiently circulated and the temperature of the liquid chemical L_CHEMICAL decreases, a solute dissolved in the liquid chemical L_CHEMICAL may be precipitated in the tube TUBE. In other words, as illustrated in FIG. 2, a solid solute S_SOLUTE may be precipitated on the inner sidewall of the tube TUBE. For example, the solid solute S_SOLUTE may be solid silica. If a tank such as the vacuum tank 160 does not employ a circulation system, a larger amount of solid solute S_SOLUTE may be precipitated in the tube of the vacuum tank 160 than in the tubes of the other tanks 110, 120, 130, and 170. However, the solid solute S_SOLUTE may be precipitated not only in the tube of the vacuum tank 160, but also in the tubes of the other tanks 110, 120, 130, and 170.

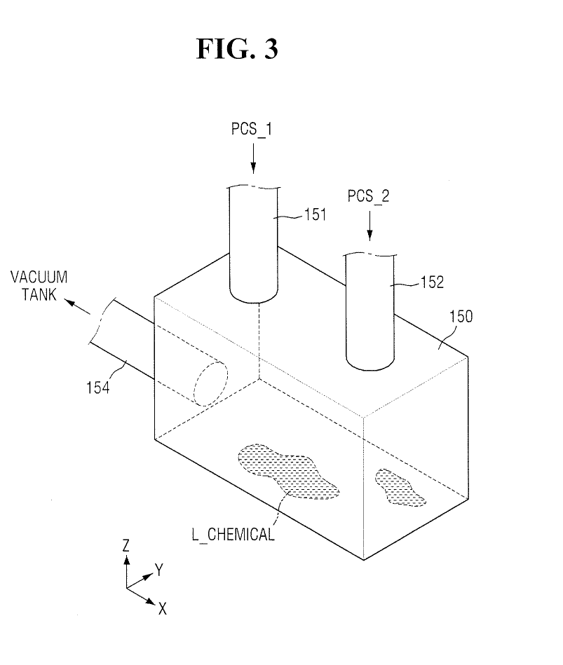

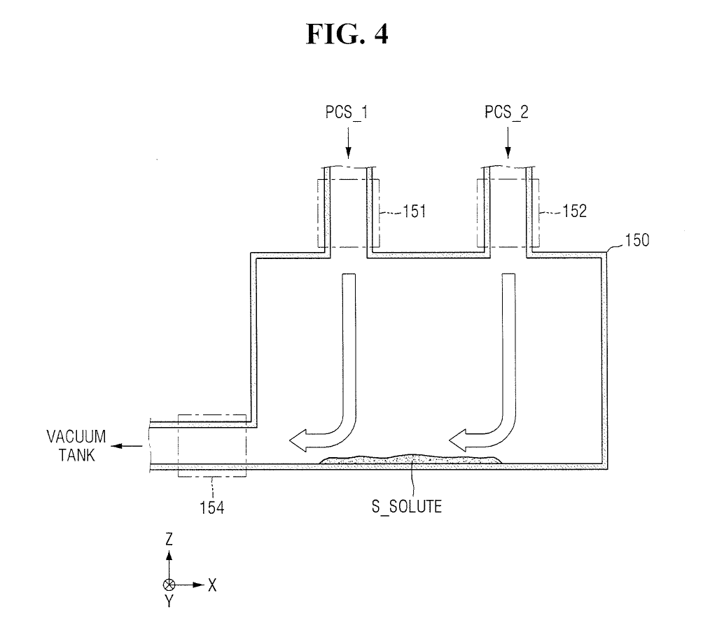

In the present example embodiment, if the solid solute S_SOLUTE is precipitated, the amount of particles may increase during wet etching. Thus, the solid solute S_SOLUTE may undesirably act as a particle source. Also, if the solid solute S_SOLUTE is precipitated on the inner sidewall of the tube TUBE, the tube TUBE may not be able to transmit light therethrough, and as a result, the level sensors LS may malfunction. Also, if the amount of solid solute S_SOLUTE precipitated increases, the tube TUBE may be clogged. The precipitation of the solid solute S_SOLUTE that may occur in the buffer tank 150 will hereinafter be described with reference to FIGS. 3 and 4.

FIG. 3 illustrates a schematic view showing a solid solute S_SOLUTE precipitated in a buffer tank according to an example embodiment. FIG. 4 is a cross-sectional view of the buffer tank according to an example embodiment.

Referring to FIGS. 3 and 4, the buffer tank 150 may include a first injection portion 151, a second injection portion 152, and a first supply portion 154. FIG. 4 shows a path along which the fifth liquid chemical provided to the buffer tank 150 flows with arrows.

The first injection portion 151 may be a path via which a liquid chemical is injected by the first process liquid chemical supply system PCS_1. The second injection portion 152 may be a path via which a liquid chemical is injected by the second process liquid chemical supply system PCS_2. The first supply portion 154 may be a path via which the fifth liquid chemical is provided to the vacuum tank 160 from the buffer tank 150.

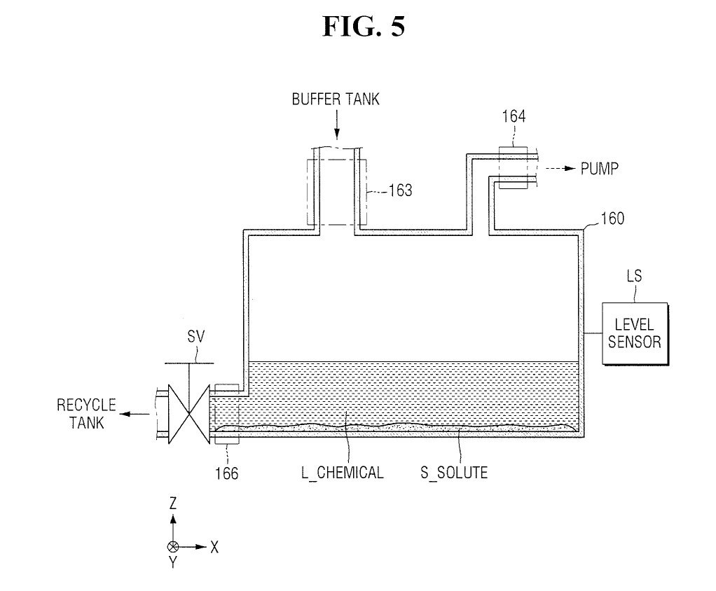

As described above, the buffer tank 150 may provide the fifth liquid chemical directly to the vacuum tank 160 without storing it. However, as illustrated in FIG. 3, if the buffer tank 150 has a flat bottom, part of a fifth liquid chemical L_CHEMICAL may remain in the buffer tank 150. The temperature of the fifth liquid chemical L_CHEMICAL remaining in the buffer tank 150 may decrease over time. Thus, as illustrated in FIG. 4, the solid solute S_SOLUTE may be precipitated out of the fifth liquid chemical L_CHEMICAL remaining in the buffer tank 150. Part of the solid solute S_SOLUTE precipitated at the bottom of the buffer tank 150 may be provided to the vacuum tank 160, the recycle tank 170, and the first sub-tank 110 and may thus become a particle source during wet etching. Also, as the amount of solid solute S_SOLUTE precipitated increases, tube clogging may become more likely to occur. The precipitation of the solid solute S_SOLUTE that may occur in the vacuum tank 160 will hereinafter be described with reference to FIG. 5.

FIG. 5 illustrates a cross-sectional view showing precipitation of the solid solute S_SOLUTE that may occur in a vacuum tank according to an example embodiment.

Referring to FIG. 5, the vacuum tank 160 may include a third injection portion 163, a first gas discharge portion 164, a second supply portion 166, the third valve SV, and a level sensor LS.

The third injection portion 163 may be a path via which the fifth liquid chemical is provided from the buffer tank 150. The first gas discharge portion 164, to which the pump 162 of FIG. 1 is connected, may be a path via which a gas is discharged from the buffer tank 150. The second supply portion 166 may be a path via which the sixth liquid chemical stored in the vacuum tank 160 is provided to the recycle tank 170. The third valve SV may be a valve for turning on or off the second supply portion 166.

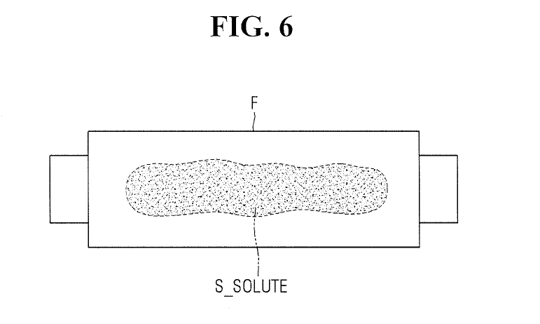

The vacuum tank 160 may not be a circulatory system. Thus, a larger amount of solid solute S_SOLUTE may be precipitated in the vacuum tank 160 than in the other tanks 110, 120, 130, and 170. Also, where the vacuum tank 160 is not a circulatory system, the sixth liquid chemical may be stored in the vacuum tank 160 until the third valve SV is turned on. Thus, a larger amount of solid solute S_SOLUTE may be precipitated in the vacuum tank 160 than in the buffer tank 150. Part of the solid solute S_SOLUTE precipitated at the bottom of the vacuum tank 160 may be provided to the recycle tank 170 and the first sub-tank 110 and may thus become a particle source during wet etching. Also, as the amount of solid solute S_SOLUTE precipitated increases, tube clogging may become more likely to occur. The precipitation of the solid solute S_SOLUTE that may occur in a filter F will hereinafter be described with reference to FIG. 6.

FIG. 6 illustrates a cross-sectional showing precipitation of the solid solute S_SOLUTE that may occur in a filter according to an example embodiment.

Referring to FIGS. 1 and 6, the solid solute S_SOLUTE may be precipitated in a filter F. In the present example embodiment, a filter F may be connected between the buffer tank 150 and the vacuum tank 160, and another filter F may be connected between the vacuum tank 160 and the recycle tank 170. The buffer tank 150 may have a structure that flows the fifth liquid chemical into the vacuum tank 160. Thus, the liquid chemical L_CHEMICAL may remain in the filter F connected between the buffer tank 150 and the vacuum tank 160. If the temperature of the liquid chemical L_CHEMICAL decreases, the solid solute S_SOLUTE may be precipitated in the filter F connected between the buffer tank 150 and the vacuum tank 160.

The vacuum tank 160 may be a system that does not circulate the sixth liquid chemical. Thus, the liquid chemical L_CHEMICAL may also remain in the filter F connected between the vacuum tank 160 and the recycle tank 170. Thus, the solid solute S_SOLUTE may also be precipitated in the filter F connected between the vacuum tank 160 and the recycle tank 170. The solid solute S_SOLUTE precipitated in these filters F may become a particle source or may interfere with the flow of the liquid chemical L_CHEMICAL by clogging the filters F.

The filters F of the first sub-tank 110, the second sub-tank 120, the main tank 130, and the recycle tank 170 are connected to heaters H and have a structure that continues to circulate the liquid chemical L_CHEMICAL. Thus, a relatively small amount of solid solute S_SOLUTE may be precipitated in the filters F of the first sub-tank 110, the second sub-tank 120, the main tank 130, and the recycle tank 170.

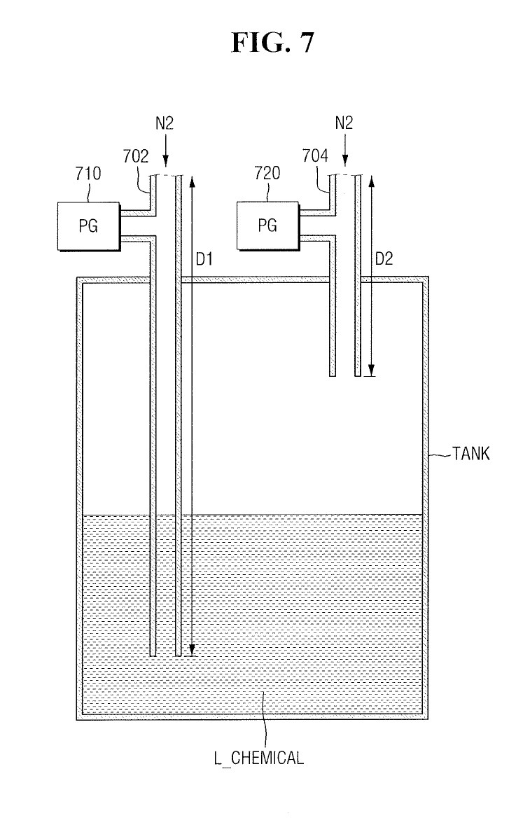

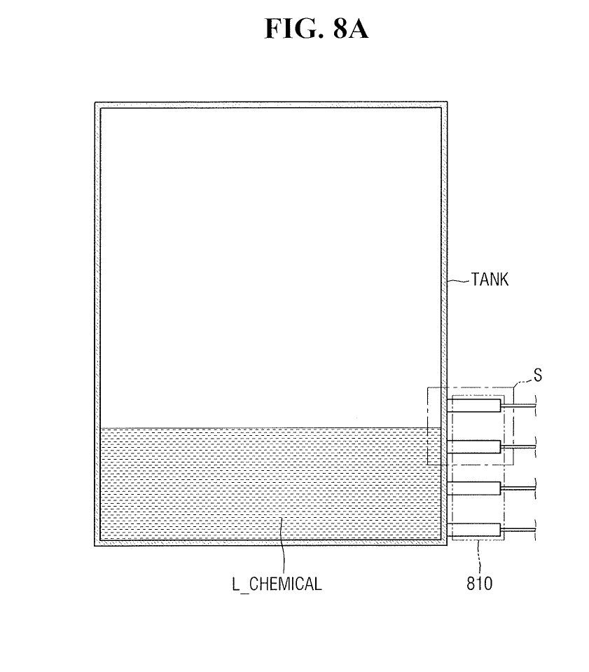

Level sensors LS according to an example embodiment will hereinafter be described with reference to FIGS. 7 through 8B.

FIG. 7 illustrates a schematic view of a level sensor according to an example embodiment.

Referring to FIG. 7, a level sensor LS may include a first gas injection portion 702, a first pressure gauge (“PG”) 710, a second gas injection portion 704, and a second pressure gauge (“PG”) 720.

An inert gas may be provided to the first gas injection portion 702. For example, a nitrogen gas (N₂) may be provided to the first gas injection portion 702. The first pressure gauge 710 may measure the internal pressure of the first gas injection portion 702. Similarly, an inert gas may be provided to the second gas injection portion 704. For example, a nitrogen gas may be provided to the second gas injection portion 704. The second pressure gauge 720 may measure the internal pressure of the second gas injection portion 704.

In the present example embodiment, a length D1 of the first gas injection portion 702 may be greater than a length D2 of the second gas injection portion 704. In an implementation, a tank TANK may include an exhaust pipe for discharging a gas or steam.

In the present example embodiment, the pressure of the first gas injection portion 702, measured by the first pressure gauge 710, may vary depending on the level of the liquid chemical L_CHEMICAL. For example, as the level of the liquid chemical L_CHEMICAL increases, the pressure of the first gas injection portion 702 may increase because the higher the level of the liquid chemical L_CHEMICAL, the higher the pressure applied to the liquid chemical L_CHEMICAL. Thus, the level of the liquid chemical L_CHEMICAL may be indirectly measured by measuring a variation in the internal pressure of the first gas injection portion 702 while supplying an inert gas into the first gas injection portion 702.

In the present example embodiment, if the level of the second pressure gauge 720 increases, the second pressure gauge 720 may send an overflow alert signal to the computing device 180. In the present example embodiment, the length by which the second gas injection portion 704 is inserted may be the maximum allowable level in the tank TANK.

In the present example embodiment, the level of the liquid chemical L_CHEMICAL may be indirectly measured by measuring the internal pressures of the first and second gas injection portions 702 and 704. Thus, since a tube TUBE is not needed on the outside of the tank TANK, the solid solute S_SOLUTE may be prevented from being precipitated by the level sensor LS.

FIG. 8A illustrates a schematic view of level sensors according to an example embodiment. FIG. 8B is an enlarged view of an area S of FIG. 8A.

Referring to FIGS. 8A and 8B, a plurality of level sensors 810 may be connected to the exterior wall of a tank TANK. For convenience, it is assumed that the level of the liquid chemical L_CHEMICAL is lower than the height at which a first level sensor 810_1 is installed and higher than the height at which a second level sensor 810_2 is installed.

In the present example embodiment, the first and second level sensors 810_1 and 810_2 may be attached on the exterior wall of the tank TANK. In the present example embodiment, the difference in electric potential between the exterior wall and the interior wall of the tank TANK may be measured by applying a voltage to the first level sensor 810_1. Thereafter, the difference in electric potential between the exterior wall and the interior wall of the tank TANK may be measured again by applying a voltage to the second level sensor 810_2. Since the liquid chemical L_CHEMICAL is an electrolyte, anions (−) contained in the liquid chemical L_CHEMICAL may approach near the exterior wall of the tank TANK where the second level sensor 810_2 is attached, when a voltage is applied to the second level sensor 810_2. Thus, the difference between the exterior wall and the interior wall of the tank TANK may be greater when a voltage is applied to the second level sensor 810_2 than when a voltage is applied to the first level sensor 810_1. In this case, the level of the liquid chemical L_CHEMICAL may be indirectly measured as being between the height at which the first level sensor 810_1 is installed and the height at which the second level sensor 810_2 is installed.

In the present example embodiment, the level of the liquid chemical L_CHEMICAL may be indirectly measured by measuring the difference in electric potential between the interior wall and the exterior wall of the tank TANK. Thus, since a tube TUBE is not needed on the outside of the tank TANK, the solid solute S_SOLUTE may be prevented from being precipitated by the level sensors 810.

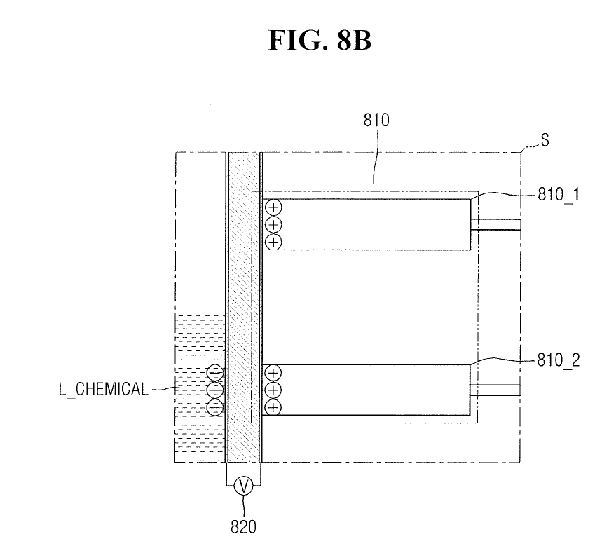

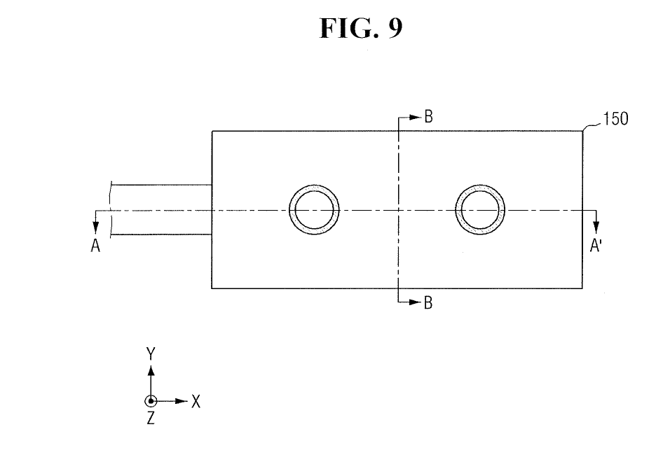

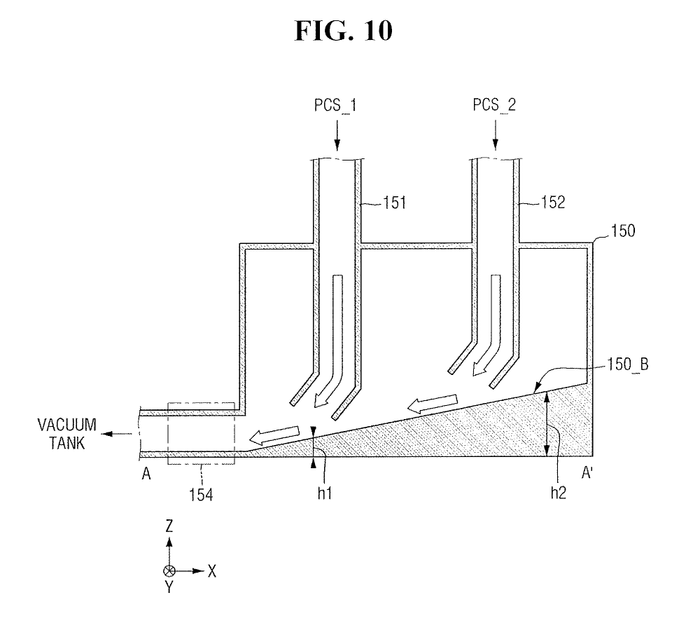

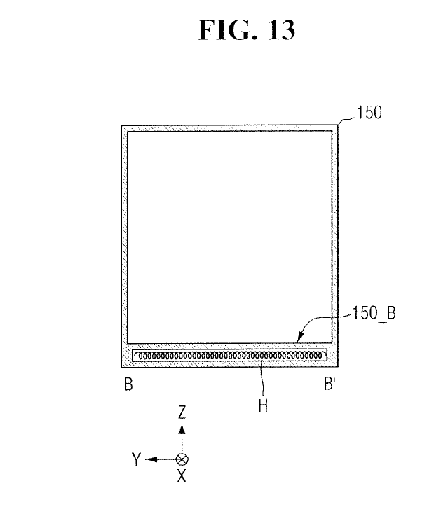

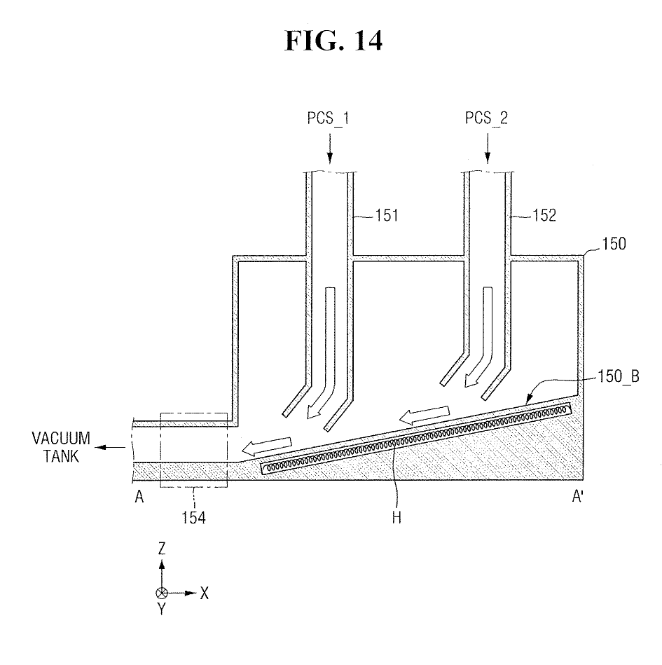

FIG. 9 illustrates a schematic view of the buffer tank of FIG. 3, as viewed from a positive Z-axis direction. FIGS. 10, 12, and 14 are cross-sectional views taken along line A-A′ of FIG. 9. FIGS. 11, 13, and 15 are cross-sectional views taken along line B-B′ of FIG. 9.

A buffer tank according to an example embodiment will hereinafter be described with reference to FIGS. 9 through 11.

In the present example embodiment, the buffer tank 150 may include the first injection portion 151, the second injection portion 152, and the first supply portion 154.

FIG. 10 is an x-z axis cross-sectional view of the buffer tank 150 as viewed from a Y-axis direction.

In the present example embodiment, the first and second injection portions 151 and 152 may be at least partially inserted in the buffer tank 150. Since the first and second injection portions 151 and 152 can be at least partially inserted in the buffer tank 150, the sidewall or the top of the buffer tank 150 may be prevented from being stained with the fifth liquid chemical during the supply of the fifth liquid chemical to the buffer tank 150. If the sidewall or the top of the buffer tank 150 is stained with the fifth liquid chemical, the solid solute S_SOLUTE may be precipitated over time and may thus become a particle source. Thus, the precipitation of the solid solute S_SOLUTE may be minimized by inserting parts of the first and second injection portions 151 and 152 in the buffer tank 150.

In the present example embodiment, as illustrated in FIG. 10, the first and second injection portions 151 and 152 may be inserted in the buffer tank 150 with their tips bent. In other words, each of the first and second injection portions 151 and 152 may include a first part extending in a first direction and a second part extending in a second direction that intersects the first direction.

In the present example embodiment, a bottom 150_B of the buffer tank 150 may be inclined toward the first supply portion 154. In other words, a height h1 of a part of the bottom 150B near the first supply portion 154 may be smaller than a height h2 of a part of the bottom 150B distant from the first supply portion 154. Thus, the fifth liquid chemical remained in the buffer tank 150 may be provided to the vacuum tank 150 by gravity. Accordingly, the amount of fifth liquid chemical remained in the buffer tank 150 may be minimized by forming the bottom 150_B of the buffer tank 150 to be inclined toward the first supply portion 154. As a result, the precipitation of the solid solute S_SOLUTE in the buffer tank 150 may be minimized.

FIG. 11 is an y-z axis cross-sectional view of the buffer tank 150 as viewed from an X-axis direction.

In the present example embodiment, the bottom 150_B of the buffer tank 150 may be inclined downwardly toward a central axis CT. In other words, an angle θ1 formed by sides 150_S of the buffer tank 150 and the bottom 150_B of the buffer tank 150 may be greater than a right angle. The fifth liquid chemical that may remain in the buffer tank 150 and may result in the precipitation of the solid solute S_SOLUTE may be more easily provided to the vacuum tank 150 by gravity. In another implementation, the bottom 150_B of the buffer tank 150 may be inclined toward the first supply portion 154, as viewed from the Y-axis direction, but may be flat, as viewed from the X-axis direction.

A buffer tank according to an example embodiment will hereinafter be described with reference to FIGS. 9, 12, and 13. Descriptions of features and elements that have already been described above will be omitted or at least simplified.

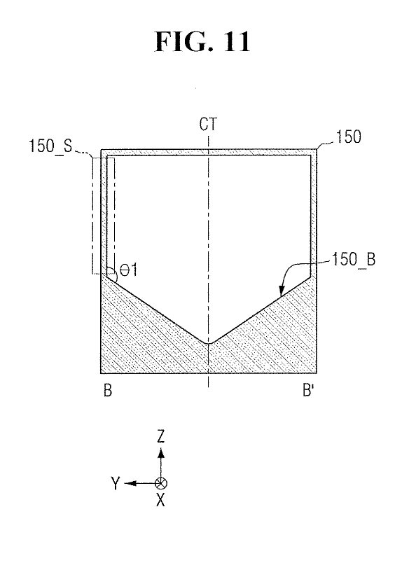

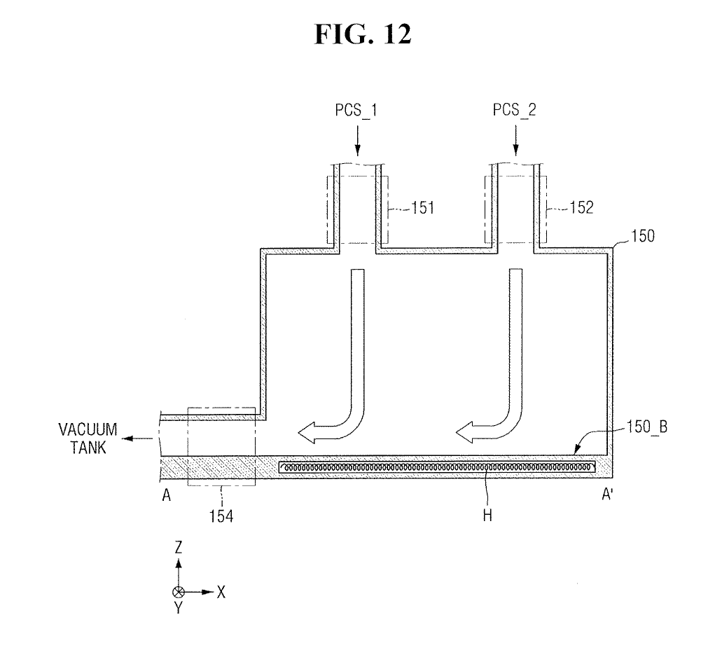

In the present example embodiment, a heater H may be connected to the bottom 150_B of the buffer tank 150. FIGS. 12 and 13 illustrate that the heater H is included in the buffer tank 150. In an implementation, the buffer tank 150 and the heater H may be provided as separate elements. In an implementation, the heater H may be implemented by providing a hot plate in a lower portion of the buffer tank 150. In the present example embodiment, since the heater H is connected to the bottom 150_B of the buffer tank 150, the solid solute S_SOLUTE may be prevented from being precipitated in the buffer tank 150.

A buffer tank according to an example embodiment will hereinafter be described with reference to FIGS. 9, 14, and 15. Descriptions of features and elements that have already been described above will be omitted or at least simplified.

In the present example embodiment, the bottom 150_B of the buffer tank 150 may be inclined toward the first supply portion 154. Also, the angle θ1 formed by sides 150_S of the buffer tank 150 and the bottom 150_B of the buffer tank 150 may be greater than a right angle. The heater H may be connected to the bottom 150_B of the buffer tank 150.

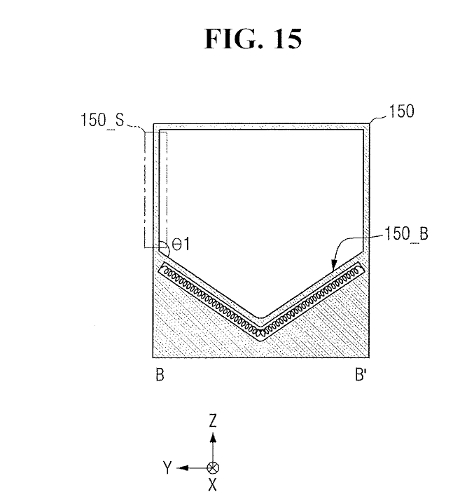

FIGS. 16 through 18 are cross-sectional views of vacuum tanks according to an example embodiment. Descriptions of features and elements that have already been described above will be omitted or at least simplified.

Referring to FIG. 16, in the present example embodiment, a bottom 160_B of the vacuum tank 160 may be inclined toward the second supply portion 166. As a result, the sixth liquid chemical in the vacuum tank 160 may be more easily provided to the recycle tank 170. Accordingly, the precipitation of the solid solute S_SOLUTE in the vacuum tank 160 may be minimized.

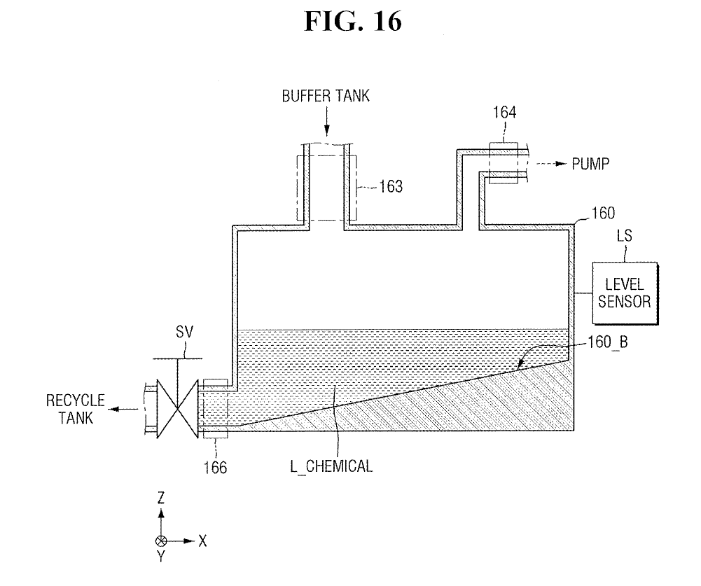

Referring to FIG. 17, in the present example embodiment, the bottom 160_B of the vacuum tank 160 may include a heater H. Accordingly, when the third valve SV is turned off, the precipitation of the solid solute S_SOLUTE in the vacuum tank 160 may be minimized.

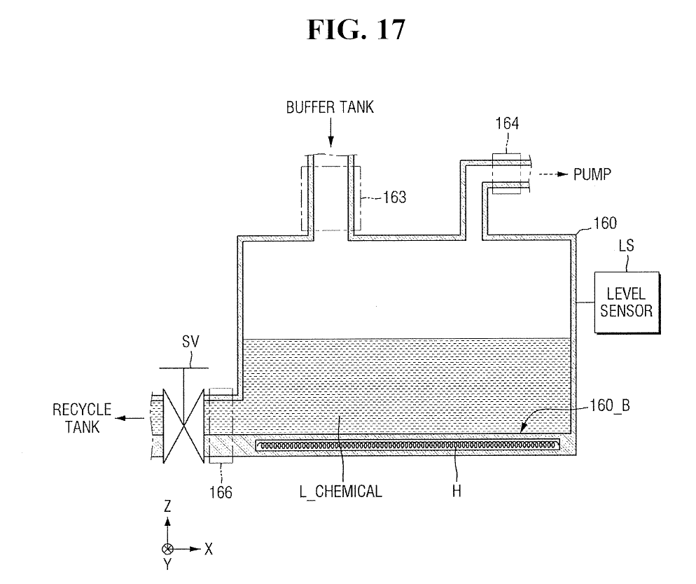

Referring to FIG. 18, in the present example embodiment, the bottom 160_B of the vacuum tank 160 may be inclined toward the second supply portion 166. Also, the bottom 160_B of the vacuum tank 160 may include a heater H. Accordingly, the precipitation of the solid solute S_SOLUTE in the vacuum tank 160 may be minimized.

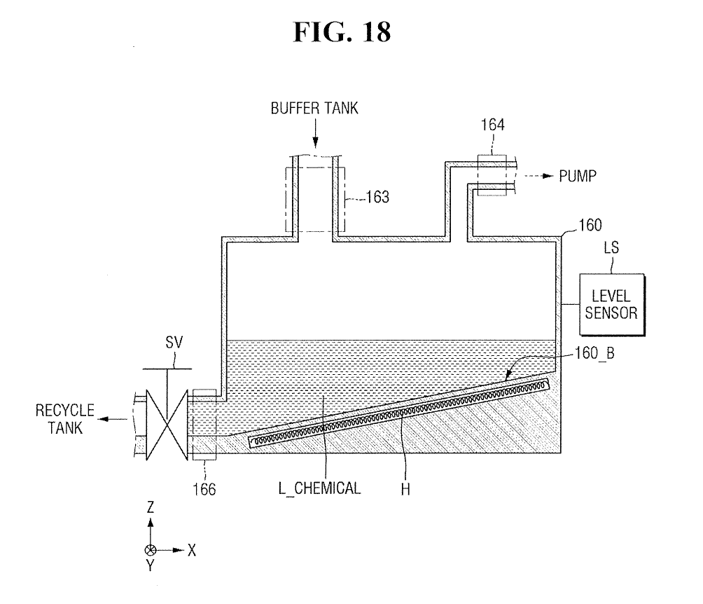

FIG. 19 illustrates a schematic view of the flushing of a filter according to an example embodiment.

Referring to FIG. 19, in the present example embodiment, when fifth and sixth valves VV_3 and VV_4 coupled to both ends of a filter F are turned on, a liquid chemical may flow through the filter F. As described above, if the liquid chemical does not flow through the filter F, the solid solute S_SOLUTE may be precipitated in the filter F. Thus, when the liquid chemical does not flow through the filter F, the fifth and sixth valves VV_3 and VV_4 may be turned off, and seventh and eighth valves WV and DV may be turned on so as to flow DI water through the filter F. In this case, the liquid chemical that may remain in the filter F may be flushed through the filter F, and as a result, the precipitation of the solid solute S_SOLUTE in the filter F may be prevented.

In the present example embodiment, the computing device 180 may control the operations of the fifth through eighth valves VV_3, VV_4, WV, and DV. For example, when the computing device 180 detects the third valve SV as being turned off, the filter F connected between the vacuum tank 160 and the recycle tank 170 may be flushed with DI water. For example, when there is no substrate provided in the process chamber 140, the computing device 180 may flush the filter F connected between the buffer tank 150 and the vacuum tank 160 with DI water. In another implementation, a user may manually turn on or off the fifth through eighth valves VV_3, VV_4, WV, and DV.

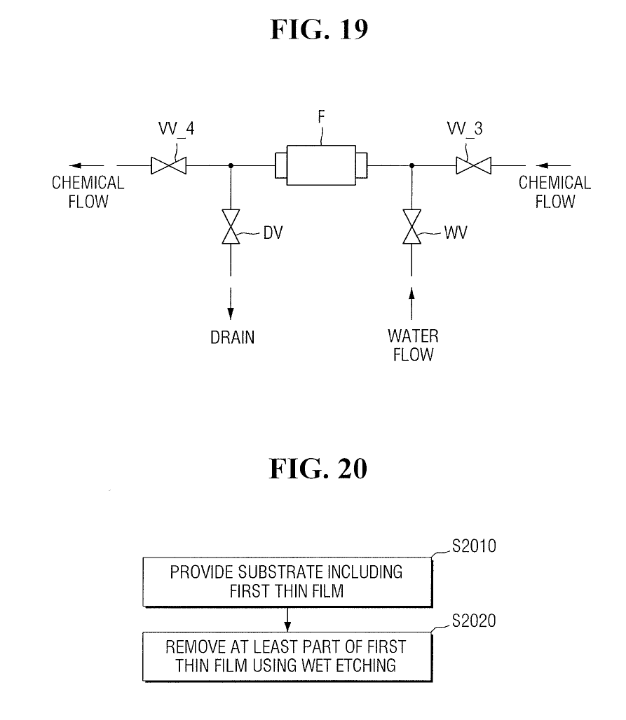

FIG. 20 is a flowchart illustrating a method of manufacturing a semiconductor device according to an example embodiment.

A substrate including a first thin film is provided (S2010). The first film may be deposited using various processes. For example, the first thin film may be deposited by chemical vapor deposition (CVD), physical vapor deposition (PVD), plasma-enhanced CVD (PECVD), metal organic CVD (MOCVD), or a thin-film process.

At least part of the first thin film is removed from the substrate using a wet etching process (S2020). The wet etching process may be performed using the liquid chemical supply system 100. For example, a first liquid chemical is provided to the process chamber 140. Thereafter, the substrate including the first thin film is provided to the process chamber 140. At least part of the first thin film is removed in the process chamber 140. A third liquid chemical provided to the process chamber 140 may be provided to the first sub-tank 110 as the first liquid chemical via the process liquid chemical recycle system PCR.

By way of summation and review, batch-type etching equipment, e.g., for SiN etching, may cause scattering defects, flow defects, and may present difficulties in controlling selection ratios. Thus, single wafer-type SiN etching equipment may be considered. Single wafer-type SiN etching equipment may be enhanced by a chemical liquid recycle system for supplying a high-temperature phosphoric acid liquid chemical into each chamber and recycling the high-temperature phosphoric acid liquid chemical after use.

As the temperature of the high-temperature phosphoric acid liquid chemical in the single wafer-type SiN etching equipment increases, the etch rate may also increase. In other words, as the temperature of the high-temperature phosphoric acid liquid chemical in the single wafer-type SiN etching equipment increases, the etch rate for SiN may also increase. However, not only the etch rate for SiN, but also the etch rate for silica (SiO₂). may increase. Thus, etch selectivity for SiN may be limited.

In order to achieve both a high etch rate and a high etch selectivity, a mixture of high-temperature phosphoric acid chemical liquid and liquid silica may be used. However, if the temperature of the high-temperature phosphoric acid liquid chemical decreases and the high-temperature phosphoric acid liquid chemical is not circulated, the liquid silica may be precipitated as solid silica and may thus become a particle source or cause tube clogging and poor sensing.

As described above, embodiments may provide a liquid chemical recycle system capable of minimizing the precipitation of a solid solute. Embodiments may also provide a liquid chemical supply system capable of minimizing the precipitation of a solid solute. Embodiments may also provide a method of manufacturing a semiconductor device using a liquid chemical recycle system capable of minimizing the precipitation of a solid solute.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A liquid chemical recycle system, comprising:
a buffer tank receiving a first liquid chemical from outside;
a vacuum tank having a vacuum pump connected thereto and receiving the first liquid chemical from the buffer tank using the vacuum pump; and
a recycle tank receiving the first liquid chemical from the vacuum tank and providing a second liquid chemical, which is a recycled first liquid chemical, to the outside,
wherein
the buffer tank includes a first injection portion, to which the first liquid chemical is provided, and a first supply portion, which provides the first liquid chemical to the vacuum tank, and
a bottom of the buffer tank is downwardly inclined toward the first supply portion so as to prevent a material contained in the first liquid chemical from being accumulated in the buffer tank.

2. The liquid chemical recycle system as claimed in claim 1, further comprising a heater to maintain or increase a temperature of the buffer tank.

3. The liquid chemical recycle system as claimed in claim 1, wherein an angle formed by a sidewall of the buffer tank and part of a bottom of the buffer tank adjacent to the sidewall is greater than a right angle.

4. The liquid chemical recycle system as claimed in claim 3, further comprising a heater to maintain or increase a temperature of the buffer tank.

5. The liquid chemical recycle system as claimed in claim 1, wherein at least part of the first injection portion is inserted in the buffer tank.

6. The liquid chemical recycle system as claimed in claim 5, wherein the first injection portion includes a first part extending in a first direction and a second part connected to the first part and extending in a second direction, which is different from the first direction.

7. The liquid chemical recycle system as claimed in claim 1, wherein the vacuum tank includes a second injection portion, to which the first liquid chemical is provided, a level sensor, which measures a level of the first liquid chemical provided to the vacuum tank, a second supply portion, which provides the first liquid chemical to the recycle tank, a first gas discharge portion, to which the vacuum pump is connected, and a first valve, which controls turning on or off of the second supply portion.

8. The liquid chemical recycle system as claimed in claim 7, wherein the level sensor is attached to an exterior wall of the vacuum tank, and measures the level of the first liquid chemical provided to the vacuum tank by applying a voltage to the exterior wall of the vacuum tank and measuring a difference in electric potential between an interior wall and the exterior wall of the vacuum tank.

9. The liquid chemical recycle system as claimed in claim 7, further comprising:
a computing device connected to the level sensor to control the turning on or off of the first valve,
wherein if the level of the first liquid chemical provided to the vacuum tank is higher than a predefined level, the computing device turns on the first valve.

10. The liquid chemical recycle system as claimed in claim 1, further comprising:
a filter disposed between the buffer tank and the vacuum tank,
wherein when the first liquid chemical is not in motion, the filter is flushed with deionized water.

11. The liquid chemical recycle system as claimed in claim 7, wherein a bottom of the vacuum tank is downwardly inclined toward the second supply portion.

12. A liquid chemical supply system, comprising:
a first storage tank including a first level sensor and storing a first liquid chemical;
a second storage tank including a second level sensor and storing a second liquid chemical;
a main tank connected to the first and second storage tanks and receiving one of the first and second liquid chemicals;
a process chamber receiving one of the first and second liquid chemicals from the main tank and in which a wet etching process is performed;
a buffer tank receiving a third liquid chemical, which is used in the wet etching process, from the process chamber; and
a vacuum tank including a third level sensor and receiving the third liquid chemical from the buffer tank,
wherein the third liquid chemical is provided to the vacuum tank along an inclined surface of the buffer tank to prevent a material contained in the third liquid chemical from being accumulated in the buffer tank.

13. The liquid chemical supply system as claimed in claim 12, further comprising a heater to maintain or increase a temperature of the buffer tank.

14. The liquid chemical supply system as claimed in claim 12, wherein an angle formed by a sidewall of the buffer tank and part of a bottom of the buffer tank adjacent to the sidewall is greater than a right angle.

15. The liquid chemical supply system as claimed in claim 12, wherein:
the buffer tank includes a first injection portion to which the third liquid chemical is provided, and
at least part of the first injection portion is inserted in the buffer tank.

16. The liquid chemical supply system as claimed in claim 12, wherein:
the first level sensor measures a level of the first liquid chemical stored in the first storage tank by applying a voltage to an exterior wall of the first storage tank,
the second level sensor measures a level of the second liquid chemical stored in the second storage tank by applying a voltage to an exterior wall of the second storage tank, and
the third level sensor measures a level of the third liquid chemical stored in the vacuum tank by applying a voltage to an exterior wall of the vacuum tank.

17. The liquid chemical supply system as claimed in claim 12, wherein:
each of the first and second level sensors includes a first gas injection portion, which has a first length, and a first pressure gauge, which measures an internal pressure of the first gas injection portion,
each of the first and second level sensors provides an inert gas into the first gas injection portion and measures a level of the first liquid chemical stored in the first storage tank and the second liquid chemical stored in the second storage tank respectively, by measuring the internal pressure of the first gas injection portion using the first pressure gauge, and
the third level sensor measures a level of the third liquid chemical stored in the vacuum tank by applying a voltage to an exterior wall of the vacuum tank.

18. The liquid chemical supply system as claimed in claim 12, further comprising:
a filter disposed between the buffer tank and the vacuum tank,
wherein when the third liquid chemical is not provided, the filter is flushed with deionized water.

19. A method of manufacturing a semiconductor device, comprising:
providing a substrate including a first thin film; and
removing at least part of the first thin film by performing a wet etching process on the substrate,
wherein:
the wet etching process involves using a liquid chemical recycle system, and
the liquid chemical recycle system includes: a buffer tank receiving a first liquid chemical from a process chamber; a vacuum tank having a vacuum pump connected thereto and receiving the first liquid chemical from the buffer tank using the vacuum pump; and a recycle tank receiving the first liquid chemical from the vacuum tank and providing a second liquid chemical, which is a recycled first liquid chemical, to the process chamber,
wherein:
the buffer tank includes a first injection portion, to which the first liquid chemical is provided, and a first supply portion, which provides the first liquid chemical to the vacuum tank, and
a bottom of the buffer tank is downwardly inclined toward the first supply portion to prevent a material contained in the first liquid chemical from being precipitated in the buffer tank.

20. The method as claimed in claim 19, wherein an angle formed by a sidewall of the buffer tank and part of a bottom of the buffer tank adjacent to the sidewall is greater than a right angle.
